(19) United States
(12) Patent Application Publication
(10) Pub. No.: US 2026/0197969 A1
(43) Pub. Date: Jul. 9, 2026

(54) LIQUID COOLING APPARATUS FOR MULTIPLE HEAT SOURCES

(71) Applicant: SHENZHEN APALTEK CO., LTD., Shenzhen (CN)

(72) Inventors: Qineng XIAO, Dongguan (CN); Dagao ZHENG, Shenzhen (CN); Jun-Chun QIU, Shenzhen (CN); Zhenhong TANG, Shenzhen (CN)

(21) Appl. No.: 19/433,644

(22) Filed: Dec. 26, 2025

(30) Foreign Application Priority Data
Jan. 6, 2025 (CN) 2025200214593

(51) Int. Cl. H05K 7/20

(52) U.S. Cl. CPC H05K 7/20272

(57) ABSTRACT

A liquid cooling apparatus for multiple heat sources, includes a water cooling radiator, first and second water cooling assemblies and a pump. The water cooling radiator includes radiator pipes having first and second radiator pipes, and an outlet chamber, an inlet chamber and a convergence chamber fluidly connected to the radiator pipes. The first and second water cooling assemblies include a water cooling block, an inlet pipe and an outlet pipe respectively. The first and second water cooling blocks include first and second inlet and outlet ports respectively. The first and second inlet pipes are fluidly connected to their respective radiator pipes and inlet port, and the first and second outlet pipes are fluidly connected to their respective outlet port and radiator pipes. The pump is arranged among the water cooling radiator, the first and second water cooling assemblies. The apparatus has a simplified structure with enhanced cooling efficiency.

### FIELD OF THE INVENTION

The technical field of the present disclosure relates to a liquid cooling apparatus, and in particular, to a liquid cooling apparatus for multiple heat sources.

### DESCRIPTION OF RELATED ART

A currently existing liquid cooling apparatus available in the market typically uses a pump to deliver coolant to the cooling module, and after the coolant absorbs the heat from the heat source, heat is released via a cooler, such as a heat sink or a heat exchanger, in order to form a circulating path. In addition, a known cooling module designed for multiple heat sources typically includes a plurality of branch pipes connected to different heat sources respectively, such as CPU, GPU or power module, in order to achieve the goal of simultaneous cooling of multiple heat sources.

A currently existing cooling module designed for multiple heat sources is able to cool multiple heat sources; however, during the process of distribution and convergence of the coolant, pressure loss may occur, resulting in an uneven distribution of the coolant flow, and the cooling efficiency may be reduced. Furthermore, a known liquid cooling apparatus for multiple heat sources is typically designed to have a plurality of branch pipes and convergence structures, such that its manufacturing cost may be higher. Consequently, its maintenance and malfunction inspection are also relatively difficult during its actual use in practice, and further improvement is required.

In view of the above, the inventor seeks to overcome the aforementioned drawbacks associated with the current technology and aims to provide an effective solution through extensive researches along with utilization of academic principles and knowledge.

### SUMMARY OF THE DISCLOSURE

An objective of the present disclosure is to provide a liquid cooling apparatus for multiple heat sources, in order to increase the cooling efficiency and to simplify the structure of the apparatus while enhancing the convenience of its use.

Another objective of the present disclosure is to provide a liquid cooling apparatus for multiple heat sources, in order to reduce the manufacturing cost and to facilitate the maintenance and malfunction inspection of the apparatus.

To achieve the aforementioned objectives, the present disclosure provides a liquid cooling apparatus for multiple heat sources, including a water cooling radiator, a first water cooling assembly, a second water cooling assembly and a pump. The water cooling radiator includes a plurality of radiator pipes and an outlet chamber, an inlet chamber and a convergence chamber fluidly connected to the radiator pipes. The radiator pipes include a plurality of first radiator pipes and a plurality of second radiator pipes. The first water cooling assembly includes a first water cooling block, a first inlet pipe and a first outlet pipe. The first water cooling block includes a first inlet port and a first outlet port. The first inlet pipe is fluidly connected to the first radiator pipes and the first inlet port, and the first outlet pipe is fluidly connected to the first outlet port and the first radiator pipes. The second water cooling assembly includes a second water cooling block, a second inlet pipe and a second outlet pipe. The second water cooling block includes a second inlet port and a second outlet port. The second inlet pipe is fluidly connected to the second radiator pipes and the second inlet port, and the second outlet pipe is fluidly connected to the second outlet port and the second radiator pipes. The pump is arranged among the water cooling radiator, the first water cooling assembly and the second water cooling assembly.

In an exemplary embodiment of the present disclosure, the first radiator pipes include a plurality of first outlet radiator pipes and a plurality of first inlet radiator pipes, the second radiator pipes include a plurality of second outlet radiator pipes and a plurality of second inlet radiator pipes, and the second outlet radiator pipes and the second inlet radiator pipes are arranged between the first outlet radiator pipes and the first inlet radiator pipes at two outer sides.

In an exemplary embodiment of the present disclosure, the first inlet pipe is fluidly connected to the first outlet radiator pipes and the first inlet port, the first outlet pipe is fluidly connected to the first outlet port and the first inlet radiator pipes; the second inlet pipe is fluidly connected to the second outlet radiator pipes and the second inlet port, the second outlet pipe is fluidly connected to the second outlet port and the second inlet radiator pipes.

In an exemplary embodiment of the present disclosure, one ends of the first outlet radiator pipes and the second outlet radiator pipes are fluidly connected to the outlet chamber, and another ends thereof are fluidly connected to the convergence chamber; one ends of the first inlet radiator pipes and the second inlet radiator pipes are fluidly connected to the inlet chamber, and another ends thereof are fluidly connected to the convergence chamber.

In an exemplary embodiment of the present disclosure, the pump includes a first pump arranged at the first water cooling assembly and a second pump arranged at the second water cooling assembly, the first pump is positioned on top of the first water cooling block, and the second pump is positioned on top of the second water cooling block.

In an exemplary embodiment of the present disclosure, the water cooling radiator includes a partition board, and the partition board is arranged between the outlet chamber and the inlet chamber.

In an exemplary embodiment of the present disclosure, the first radiator pipes include a plurality of first outlet radiator pipes and a plurality of first inlet radiator pipes, the second radiator pipes include a plurality of second outlet radiator pipes and a plurality of second inlet radiator pipes, and the first inlet radiator pipes and the second inlet radiator pipes are arranged between the first outlet radiator pipes and the second outlet radiator pipes at two outer sides.

In an exemplary embodiment of the present disclosure, the outlet chamber includes a first outlet chamber and a second outlet chamber; the convergence chamber includes a first convergence chamber and a second convergence chamber; one ends of the first outlet radiator pipes are fluidly connected to the first outlet chamber, and another ends thereof are fluidly connected to the first convergence chamber, one ends of the first inlet radiator pipes are fluidly connected to the inlet chamber, and another ends thereof are fluidly connected to the first convergence chamber; one ends of the second outlet radiator pipes are fluidly connected to the second outlet chamber, and another ends thereof are fluidly connected to the second convergence chamber, one ends of the second inlet radiator pipes are fluidly connected to the inlet chamber, and another ends thereof are fluidly connected to the second convergence chamber.

In an exemplary embodiment of the present disclosure, the water cooling radiator includes a plurality of first partition boards and a second partition board. The first partition boards are arranged between the first outlet chamber and the inlet chamber, and between the second outlet chamber and the inlet chamber. The second partition board is arranged between the first convergence chamber and the second convergence chamber.

In an exemplary embodiment of the present disclosure, the pump is arranged on the water cooling radiator and is positioned between the first inlet radiator pipes and the second inlet radiator pipes.

In comparison to the known art, the liquid cooling apparatus for multiple heat sources of the present disclosure may be divided into two circulating water paths according to the arrangement of the first water cooling assembly and the second water cooling assembly. In addition, the pump may be arranged among the water cooling radiator, the first water cooling assembly and the second water cooling assembly to increase the pressure of the circulating water paths, in order to increase the flow velocity and cooling efficiency of the coolant. Furthermore, the liquid cooling apparatus of the present disclosure has a simple structure and is able to cool multiple heat sources at the same time such that its practicalness and convenience of use are enhanced.

### BRIEF DESCRIPTION OF THE DRAWINGS

FIG. 1 is a perspective outer appearance view of the liquid cooling apparatus for multiple heat sources of the present disclosure;

FIG. 2 is a cross-sectional view of the water cooling radiator of the present disclosure;

FIG. 3 is a perspective outer appearance view of another exemplary embodiment of the liquid cooling apparatus for multiple heat sources of the present disclosure; and

FIG. 4 is a cross-sectional view of another exemplary embodiment of the water cooling radiator of the present disclosure.

### DETAILED DESCRIPTION

The technical contents of the present disclosure will become apparent with the detailed description of embodiments accompanied with the illustration of related drawings as follows. It is intended that the embodiments and drawings disclosed herein are to be considered illustrative rather than restrictive.

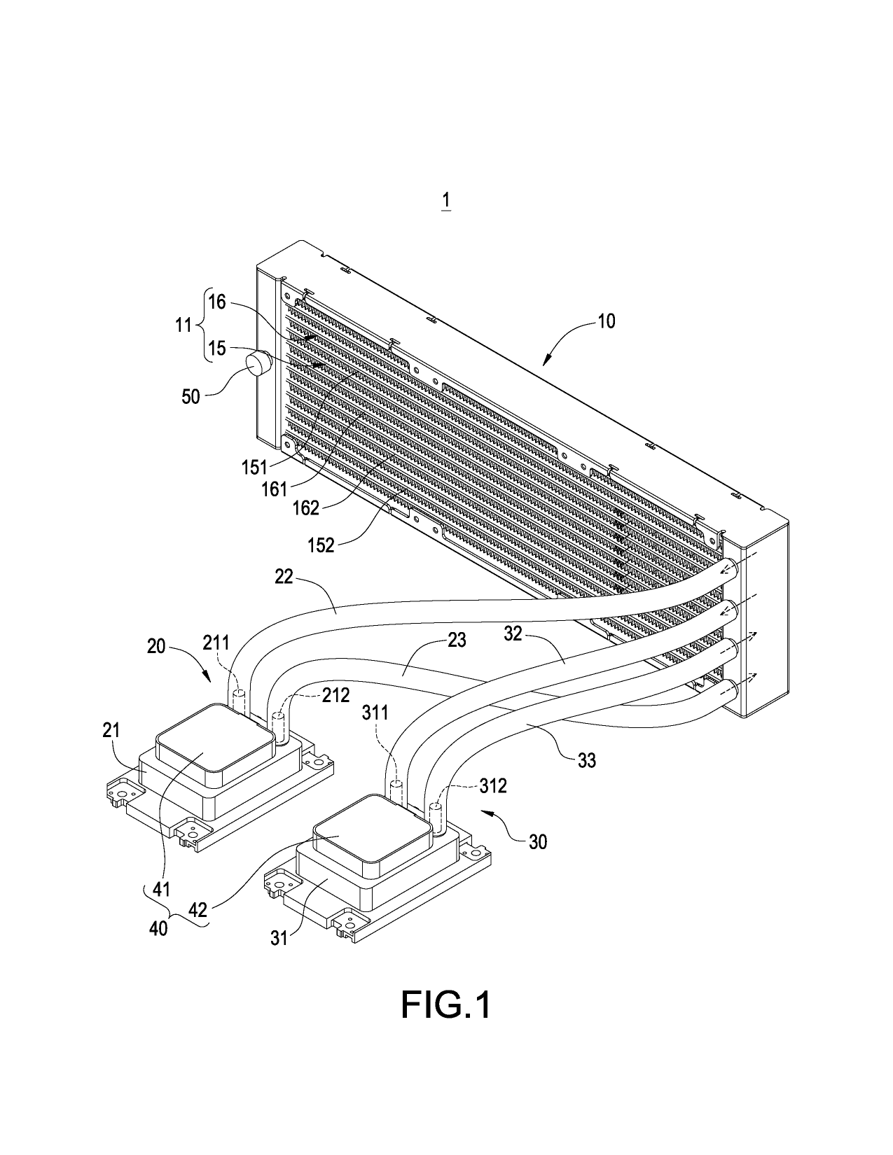

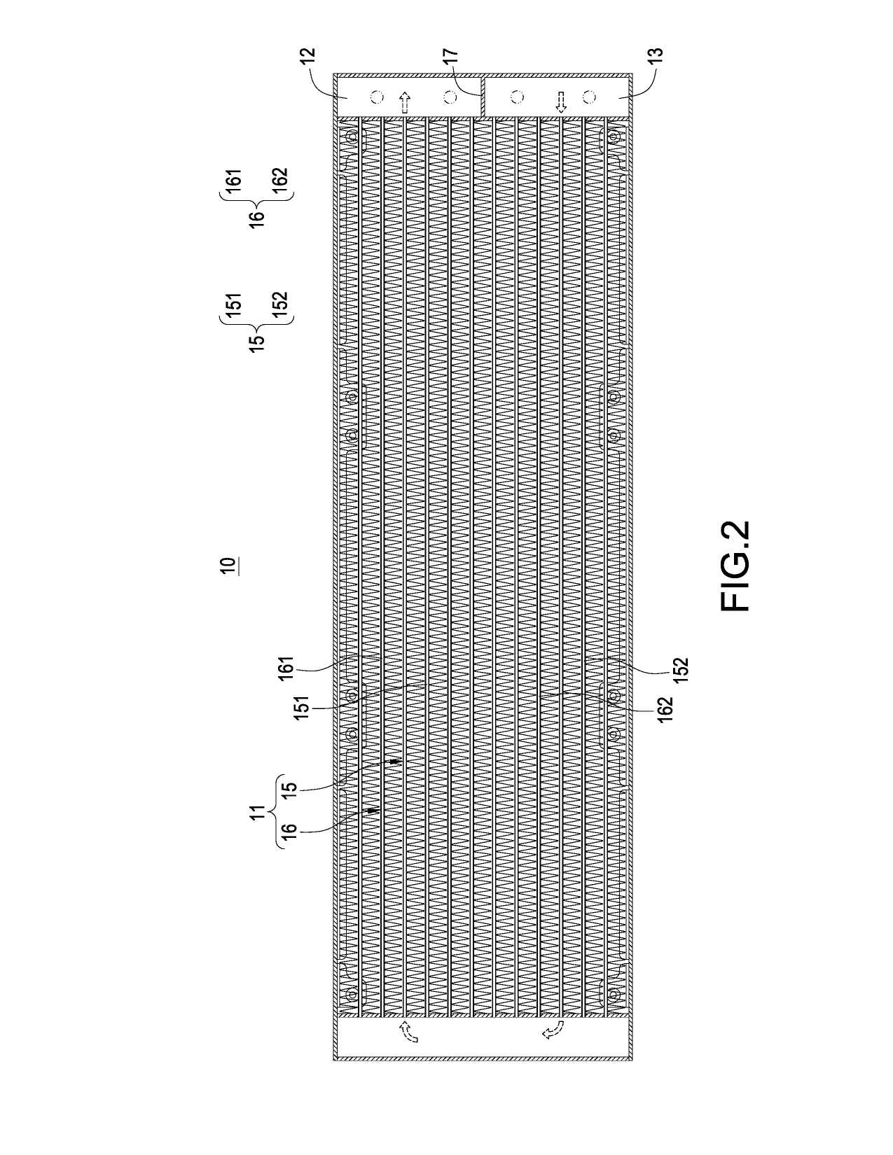

Please refer to FIG. 1 and FIG. 2, showing a perspective outer appearance view of the liquid cooling apparatus for multiple heat sources of the present disclosure and a cross-sectional view of the water cooling radiator of the present disclosure. The present disclosure provides a liquid cooling apparatus 1 for multiple heat sources, including a water cooling radiator 10, a first water cooling assembly 20, a second water cooling assembly 30 and at least one pump 40. The first water cooling assembly 20 and the second water cooling assembly 30 are fluidly connected to the water cooling radiator 10, in order to cool multiple heat sources (not shown in the drawings). In addition, the pump 40 is fluidly connected to the water cooling radiator 10 or the first water cooling assembly 20 and the second water cooling assembly 30, in order to increase the pressure of the circulating water paths and to enhance the cooling efficiency. Please refer to following detailed description of the liquid cooling apparatus 1 for multiple heat sources.

The water cooling radiator 10 includes a plurality of radiator pipes 11 and an outlet chamber 12, an inlet chamber 13 and a convergence chamber 14 fluidly connected to the radiator pipes 11. The radiator pipes 11 include a plurality of first radiator pipes 15 and a plurality of second radiator pipes 16. In addition, the first radiator pipes 15 include a plurality of first outlet radiator pipes 151 and a plurality of first inlet radiator pipes 152. The second radiator pipes 16 include a plurality of second outlet radiator pipes 161 and a plurality of second inlet radiator pipes 162. In this exemplary embodiment, the second outlet radiator pipes 161 and the second inlet radiator pipes 162 are arranged between the first outlet radiator pipes 151 and the first inlet radiator pipes 152 at two outer sides.

The first water cooling assembly 20 includes a first water cooling block 21, a first inlet pipe 22 and a first outlet pipe 23. The first water cooling block 21 includes a first inlet port 211 and a first outlet port 212. The first inlet pipe 22 is fluidly connected to the first outlet radiator pipes 151 of the first radiator pipes 15 and the first inlet port 211. The first outlet pipe 23 is fluidly connected to the first outlet port 212 and the first inlet radiator pipes 152 of the first radiator pipes 15.

Furthermore, the second water cooling assembly 30 includes a second water cooling block 31, a second inlet pipe 32 and a second outlet pipe 33. The second water cooling block 31 includes a second inlet port 311 and a second outlet port 312. The second inlet pipe 32 is fluidly connected to the second outlet radiator pipes 161 of the second radiator pipes 16 and the second inlet port 311. The second outlet pipe 33 is fluidly connected to the second outlet port 312 and the second inlet radiator pipes of the second radiator pipes.

To be more specific, one ends of the first outlet radiator pipes 151 and the second outlet radiator pipes 161 are fluidly connected to the outlet chamber 12, and another ends thereof are fluidly connected to the convergence chamber 14. In addition, one ends of the first inlet radiator pipes 152 and the second inlet radiator pipes 162 are fluidly connected to the inlet chamber 13, and another ends thereof are fluidly connected to the convergence chamber 14.

The pump 40 is arranged among the water cooling radiator 10, the first water cooling assembly 20 and the second water cooling assembly 30. In an exemplary embodiment, the pump 40 includes a first pump 41 arranged at the first water cooling assembly 20 and a second pump 42 arranged at the second water cooling assembly 30. Furthermore, the first pump 41 is positioned on top of the first water cooling block 21. The second pump 42 is positioned on top of the second water cooling block 31.

It shall be noted that the water cooling radiator 10 of the present disclosure further includes a partition board 17. The partition board 17 is arranged between the outlet chamber 12 and the inlet chamber 13. In addition, the water cooling radiator 10 of the present disclosure includes a pressure relief valve 50 arranged at the convergence chamber 14. When an internal of the liquid cooling apparatus 1 for multiple heat sources of the present disclosure contains air, the pressure relief valve 50 may be used to release the internal air.

Accordingly, the liquid cooling apparatus 1 for multiple heat sources of the present disclosure may be divided into two circulating water paths based on the arrangement of the first water cooling assembly 20 and the second water cooling assembly 30. In the first circulating water path, the coolant flows out from the outlet chamber 12 and enters the first inlet pipe 22 and the first water cooling head 21, then flows out of the first outlet pipe 23 to enter the inlet chamber 13. Next, the coolant passes through the first inlet radiator pipes 152 and enters the convergence chamber 14, following which it passes through the first outlet radiator pipes 151 to enter the outlet chamber 12, and further flows to the first inlet pipe 22. Accordingly, based on the circulation of this path, the coolant undergoes heat exchange at the first water cooling head 21, such that the first water cooling head 21 is able to cool a heat generating source.

Similarly, in the second circulating water path, the coolant flows out from the outlet chamber 12 and enters the second inlet pipe 32 and the second water cooling head 31, then flows out of the second outlet pipe 33 to enter the inlet chamber 13. Next, the coolant passes through the second inlet radiator pipes 162 and enters the convergence chamber 14, following which it passes through the second outlet radiator pipes 161 to enter the outlet chamber 12, and further flows to the second inlet pipe 32. Accordingly, based on the circulation of this path, the coolant undergoes heat exchange at the second water cooling head 31, such that the second water cooling head 31 is able to cool a heat generating source.

It shall be noted that the first pump 41 is fluidly connected to the first water cooling block 21 in order to increase the pressure of the first circulating water path and to further increase the flow velocity of the coolant, thereby enhancing the cooling efficiency. Moreover, the second pump 42 is fluidly connected to the second water cooling block 31 in order to increase the pressure of the second circulating water path and to further increase the flow velocity of the coolant, thereby enhancing the cooling efficiency.

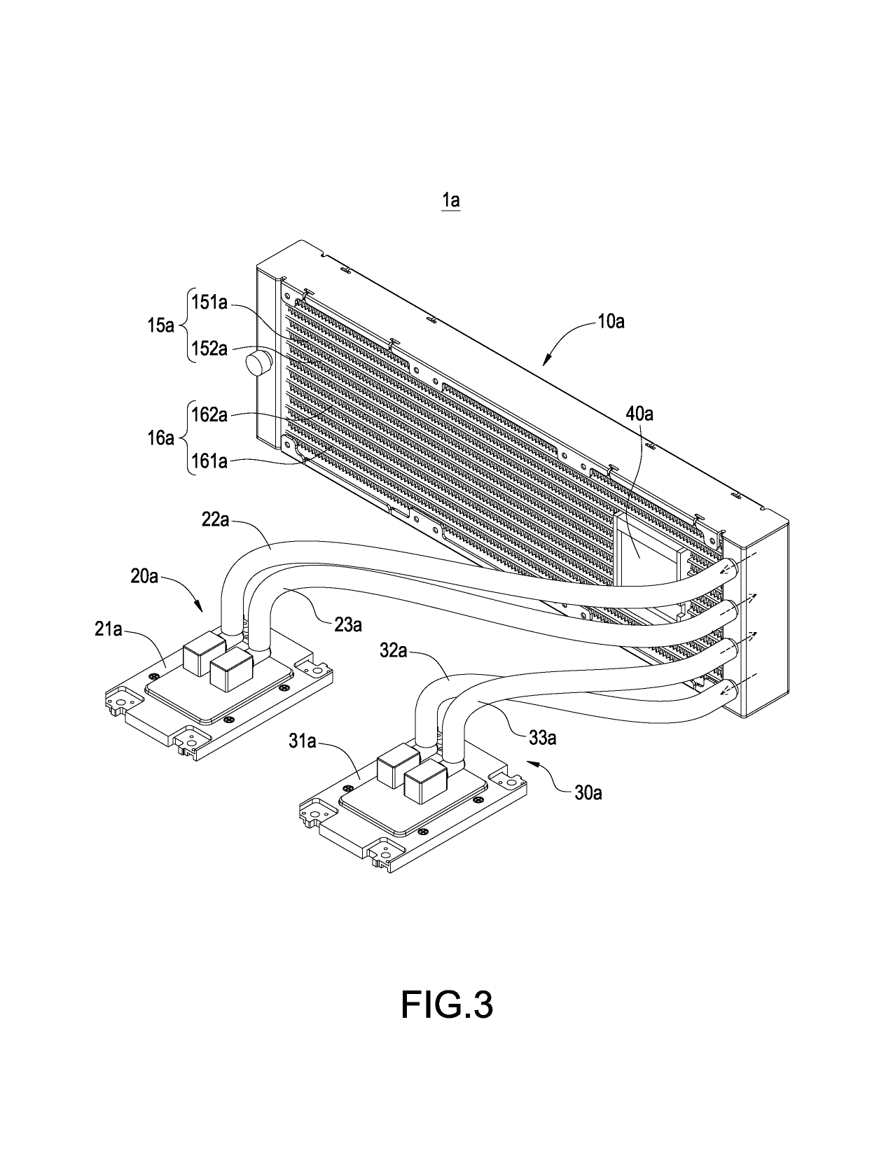

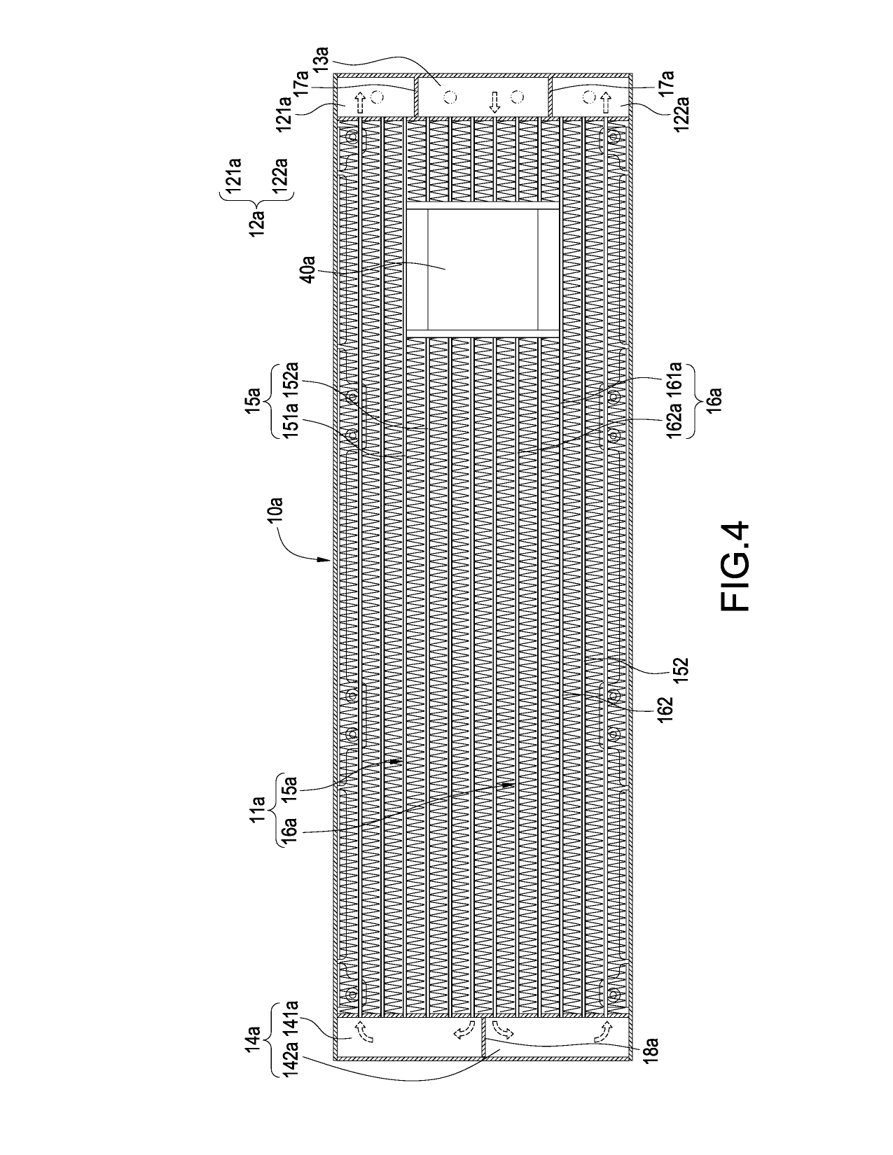

Please refer to FIG. 3 and FIG. 4, showing a perspective outer appearance view of another exemplary embodiment of the liquid cooling apparatus for multiple heat sources of the present disclosure and a cross-sectional view of the water cooling radiator of the present disclosure. This exemplary embodiment is generally identical to the previous exemplary embodiment. The liquid cooling apparatus 1a for multiple heat sources include a water cooling radiator 10a, a first water cooling assembly 20a, a second water cooling assembly 30a and at least one pump 40a. The water cooling radiator 10a includes a plurality of radiator pipes 11a, an outlet chamber 12a (including a first outlet chamber 121a and a second outlet chamber 122a), an inlet chamber 13a and a convergence chamber 14a (including a first convergence chamber 141a and a second convergence chamber 142a). The radiator pipes 11a include a plurality of first radiator pipes 15a and a plurality of second radiator pipes 16a. In addition, the first radiator pipes 15a include a plurality of first outlet radiator pipes 151a and a plurality of first inlet radiator pipes 152a. The second radiator pipes 16a include a plurality of second outlet radiator pipes 161a and a plurality of second inlet radiator pipes 162a. In this exemplary embodiment, the first inlet radiator pipes 152a and the second inlet radiator pipes 162a are arranged between the first outlet radiator pipes 151a and the second outlet radiator pipes 161a at two outer sides.

In this exemplary embodiment, one ends of the first outlet radiator pipes 151a are fluidly connected to the outlet chamber 121a, and another ends thereof are fluidly connected to the first convergence chamber 141a. In addition, one ends of the first inlet radiator pipes 152a are fluidly connected to the inlet chamber, and another ends thereof are fluidly connected to the first convergence chamber 141a. One ends of the second outlet radiator pipes 161a are fluidly connected to the second outlet chamber 122a, and another ends thereof are fluidly connected to the second convergence chamber 142a. Furthermore, one ends of the second inlet radiator pipes 162a are fluidly connected to the inlet chamber, and another ends thereof are fluidly connected to the second convergence chamber 142a.

It shall be noted that the water cooling radiator 10a further comprises a plurality of first partition boards 17a and a second partition board 18a. The first partition boards 17a are arranged between the first outlet chamber 121a and the inlet chamber 13a, and between the second outlet chamber 122a and the inlet chamber 13a, respectively. In addition, the second partition board 18a is arranged between the first convergence chamber 141a and the second convergence chamber 142a.

Furthermore, the first water cooling assembly 20a includes a first water cooling block 21a, a first inlet pipe 22a and a first outlet pipe 23a. The second water cooling assembly 30a includes a second water cooling block 31a, a second inlet pipe 32a and a second outlet pipe 33a. The connection arrangement for the first water cooling assembly 20a and the second water cooling assembly 30a is generally the same as the ones of the previous exemplary embodiment; therefore, its details are omitted.

The main difference between this exemplary embodiment and the previous exemplary embodiment refers to that the pump 40a is arranged at the water cooling radiator 10a and is positioned between the first inlet radiator pipes 152a and the second inlet radiator pipes 162a.

Accordingly, the liquid cooling apparatus 1a for multiple heat sources of the present disclosure may be divided into two circulating water paths based on the arrangement of the first water cooling assembly 20a and the second water cooling assembly 30a. In the first circulating water path, the coolant flows out from the first outlet chamber 121a and enters the first inlet pipe 22a and the first water cooling head 21a, then flows out of the first outlet pipe 23a to enter the inlet chamber 13a. Next, the coolant passes through the first inlet radiator pipes 152a and enters the first convergence chamber 141a, following which it passes through the first outlet radiator pipes 151a to enter the first outlet chamber 121a, and further flows to the first inlet pipe 22a. Accordingly, based on the circulation of this path, the coolant undergoes heat exchange at the first water cooling head 21a, such that the first water cooling head 21a is able to cool a heat generating source.

Similarly, in the second circulating water path, the coolant flows out from the second outlet chamber 122a and enters the second inlet pipe 32a and the second water cooling head 31a, then flows out of the second outlet pipe 33a to enter the inlet chamber 13a. Next, the coolant passes through the second inlet radiator pipes 162a and enters the second convergence chamber 142a, following which it passes through the second outlet radiator pipes 161a to enter the second outlet chamber 122a, and further flows to the second inlet pipe 32a. Accordingly, based on the circulation of this path, the coolant undergoes heat exchange at the second water cooling head 31a, such that the second water cooling head 31a is able to cool a heat generating source.

It shall be noted that the water pump 40a is able to increase the water pressure of the first water cooling assembly 20a and the second water cooling assembly 30a, in order to enhance the cooling efficiency.

The above description is provided to illustrate the exemplary embodiments of the present disclosure only such that it shall not be treated as limitation to the claimed scope of the present disclosure. In addition, any equivalent modification made based on the present disclosure shall be considered to be within the claimed scope of the present disclosure.

What is claimed is:

1. A liquid cooling apparatus for multiple heat sources, comprising:
a water cooling radiator comprising a plurality of radiator pipes and an outlet chamber, an inlet chamber and a convergence chamber fluidly connected to the radiator pipes, and the radiator pipes comprising a plurality of first radiator pipes and a plurality of second radiator pipes;
a first water cooling assembly comprising a first water cooling block, a first inlet pipe and a first outlet pipe, the first water cooling block comprising a first inlet port and a first outlet port, the first inlet pipe fluidly connected to the first radiator pipes and the first inlet port, the first outlet pipe fluidly connected to the first outlet port and the first radiator pipes;
a second water cooling assembly comprising a second water cooling block, a second inlet pipe and a second outlet pipe, the second water cooling block comprising a second inlet port and a second outlet port, the second inlet pipe fluidly connected to the second radiator pipes and the second inlet port, the second outlet pipe fluidly connected to the second outlet port and the second radiator pipes; and
at least one pump arranged among the water cooling radiator, the first water cooling assembly and the second water cooling assembly.

2. The liquid cooling apparatus for multiple heat sources according to claim 1, wherein the first radiator pipes comprise a plurality of first outlet radiator pipes and a plurality of first inlet radiator pipes, the second radiator pipes comprise a plurality of second outlet radiator pipes and a plurality of second inlet radiator pipes, and the second outlet radiator pipes and the second inlet radiator pipes are arranged between the first outlet radiator pipes and the first inlet radiator pipes at two outer sides.

3. The liquid cooling apparatus for multiple heat sources according to claim 2, wherein the first inlet pipe is fluidly connected to the first outlet radiator pipes and the first inlet port, the first outlet pipe is fluidly connected to the first outlet port and the first inlet radiator pipes; the second inlet pipe is fluidly connected to the second outlet radiator pipes and the second inlet port, the second outlet pipe is fluidly connected to the second outlet port and the second inlet radiator pipes.

4. The liquid cooling apparatus for multiple heat sources according to claim 2, wherein one ends of the first outlet radiator pipes and the second outlet radiator pipes are fluidly connected to the outlet chamber, and another ends thereof are fluidly connected to the convergence chamber; one ends of the first inlet radiator pipes and the second inlet radiator pipes are fluidly connected to the inlet chamber, and another ends thereof are fluidly connected to the convergence chamber.

5. The liquid cooling apparatus for multiple heat sources according to claim 2, wherein the at least one pump comprises a first pump arranged at the first water cooling assembly and a second pump arranged at the second water cooling assembly, the first pump is positioned on top of the first water cooling block, and the second pump is positioned on top of the second water cooling block.

6. The liquid cooling apparatus for multiple heat sources according to claim 1, wherein the water cooling radiator comprises a partition board, and the partition board is arranged between the outlet chamber and the inlet chamber.

7. The liquid cooling apparatus for multiple heat sources according to claim 1, wherein the first radiator pipes comprise a plurality of first outlet radiator pipes and a plurality of first inlet radiator pipes, the second radiator pipes comprise a plurality of second outlet radiator pipes and a plurality of second inlet radiator pipes, and the first inlet radiator pipes and the second inlet radiator pipes are arranged between the first outlet radiator pipes and the second outlet radiator pipes at two outer sides.

8. The liquid cooling apparatus for multiple heat sources according to claim 7, wherein the outlet chamber comprises a first outlet chamber and a second outlet chamber, the convergence chamber comprises a first convergence chamber and a second convergence chamber; one ends of the first outlet radiator pipes are fluidly connected to the first outlet chamber, and another ends thereof are fluidly connected to the first convergence chamber, one ends of the first inlet radiator pipes are fluidly connected to the inlet chamber, and another ends thereof are fluidly connected to the first convergence chamber; one ends of the second outlet radiator pipes are fluidly connected to the second outlet chamber, and another ends thereof are fluidly connected to the second convergence chamber, one ends of the second inlet radiator pipes are fluidly connected to the inlet chamber, and another ends thereof are fluidly connected to the second convergence chamber.

9. The liquid cooling apparatus for multiple heat sources according to claim 8, wherein the water cooling radiator comprises a plurality of first partition boards and a second partition board, the first partition boards are arranged between the first outlet chamber and the inlet chamber, and between the second outlet chamber and the inlet chamber, the second partition board is arranged between the first convergence chamber and the second convergence chamber.

10. The liquid cooling apparatus for multiple heat sources according to claim 7, wherein the at least one pump is arranged on the water cooling radiator and is positioned between the first inlet radiator pipes and the second inlet radiator pipes.
